(19) United States
(12) Patent Application Publication
(10) Pub. No.: US 2007/0029664 A1
(43) Pub. Date: Feb. 8, 2007

(54) Integrated circuit package and method of assembling the same

(75) Inventors: Anwar A. Mohammed, San Jose, CA (US); Joseph A. Hornung, Cupertino, CA (US)

Correspondence Address: KOPPEL, PATRICK & HEYBL, 555 ST. CHARLES DRIVE, SUITE 107, THOUSAND OAKS, CA, 91360, US

(73) Assignee: CREE MICROWAVE, LLC.

(21) Appl. No.: 11/198,679

(22) Filed: Aug. 5, 2005

(51) Int. Cl. H01L 23/34; H01L 23/10

(52) U.S. Cl. 257/706

(57) ABSTRACT

Flexible, adhesive materials are used to secure integrated circuit package components together. The die is secured to the heat sink, the ringframe to the heat sink and the leadframe to the ringframe, using epoxy materials that flex over the operational temperature range of the circuit package. The flexibility of the adhesives accommodates large differences in expansion and contraction of CTE-mismatched materials. The heat sink and ringframe materials are neither restricted to CTE-compatible materials nor to materials that are compatible with high-temperature attachment processes. Adhesive mounting of the die avoids the use of lead-based solders used in typical assembly processes.

### BACKGROUND OF THE INVENTION

1. Field of the Invention

This invention relates to packages for integrated circuit devices, and more particularly to packages having coefficient of thermal expansion (CTE) mismatches between package components.

2. Description of Related Art

Different packaging has been developed for integrated circuits, such as transistors, operating in different environments and under different operating characteristics. For example, radio frequency (“RF”) communications rely on high power transistors to boost the power of RF signals being sent to transmitting antenna. The increasing demand for high bandwidth mobile phone services has resulted in a need for efficient high frequency, relatively high power transistors. In one application, banks of such devices can be used in mobile phone stations to boost RF signals. Because of the high frequency and high power operation, the transistors can operate at high temperature, and to dissipate this heat, the transistors can be mounted in conjunction with a heat sink that is integral with the transistor package.

FIG. 1 shows a prior art heat sink and transistor assembly 10 that can be used to carry many different types of transistors, but as shown is carrying a single lateral double diffuse metal oxide silicon (LDMOS) die 12 having a transistor formed on it. The assembly 10 includes a heat-dissipating substrate 14 commonly referred to as a flange, a dielectric insulator 16 commonly referred to as a ringframe or spacer that is brazed to the flange 14, which electrically isolates the flange 14 from a conductive leadframe formed by two separate plates 18, 20. The plates 18, 20 are typically bonded or brazed to the ringframe 16. The thickness of the ringframe 16 is selected to carry the plates 18, 20 at the proper height in relation to the die 12, and can be selected to change the electrical characteristics of the package.

The source of the transistor is electrically connected to the bottom of the die 12 and when packaged is electrically accessible through the typically gold plated flange 14 upon which it is mounted. The gate and drain of the transistor are connected to pads on an upper surface of the die 12 and are connected through first and second wirebonds 22, 24, respectively to the conductive plates 18, 20 which extend out to form the package gate and drain leads. Once these interconnections have been formed, the die is encapsulated by a plastic or ceramic lid (not shown) that is bonded to the assembly.

The flange 14 is made of heat-dissipating or otherwise thermal conductivity enhanced material which typically has a coefficient of thermal expansion (“CTE”) compatible with material forming the transistor which is typically gallium arsenide (“GaAs”) or silicon. “CTE compatible” means the materials are thermally compatible (due to thermal expansion and contraction) over the temperature operating range. For example, the flange may be formed from a sintered mixture of copper and tungsten powders whose concentrations have been selected to achieve a compatible CTE. The ringframe is typically made from a ceramic such as alumina or other electrically insulating material capable of being bonded to the flange and having a CTE compatible with the CTE of the flange material.

The heat sink assembly 10, with its flange 14, ringframe 16 and plates 18, 20, is typically fabricated prior to attachment of the die 12. The plates 16, 18 are bonded to the ringframe 16, and the ringframe 16 is bonded to the flange 14. Typically, both bonds are formed using high-temperature processes that involve temperatures of about 400° C. One such process known as CuSil brazing uses Cu—Ag braze alloys.

The die 12 is then attached to the flange 14 through the central aperture of the ringframe 16 also using a high-temperature process, such as gold-silicon eutectic brazing. This type of brazing involves heating the flange 14 to about 400° C., then typically placing the die 12 manually under the aid of a microscope to avoid damaging the plates 18, 20 or ringframe 16. At this temperature the thin layer of gold plating on the upper surface of the flange combines with the lower surface of the silicon die to form gold-silicon eutectic.

The brazing process used to secure the ringframe 16 to the flange 14 tends to introduce materials, such as Sn and Ag, into the package that can migrate under conditions of high humidity and in the presence of an applied voltage. This migration of metal has been demonstrated to cause reliability issues in RF LDMOS packages.

The brazing process also forms rigid connections between the ringframe 16 and the flange 14 and the plates 16, 18 and the ringframe 16 that force the components to expand and contract together at the same rate over temperature ranges. Therefore, it is necessary that the materials forming the flange 14, ringframe 16 and plates. 18,20 are CTE compatible. If the CTEs of the materials forming these components are not closely matched, one of the components, most often the ringframe 16, which is usually made of ceramic, will fail mechanically in the form of cracks.

In typical LDMOS packages having CTE compatible components, the flange 14 is a copper alloy such as CuW or laminates of CuMoCu that have a close CTE to the ceramic ringframe. Copper alloys are more expensive than a pure copper heat sink and offer much less thermal performance (170-200° C./mK vs. 400° C./mK for copper), but are required because their CTEs are much closer to ceramic than the CTE of pure copper.

U.S. Pat. No. 6,462,413 discloses a LDMOS package having a die that is attached to a flange using a high-temperature process and a leadframe that may be attached to the ringframe using low-temperature epoxy processes and a ringframe that may also be attached to a flange using low-temperature epoxy processes. However, because the die attachment process is high-temperature, the die must be attached prior to the low-temperature attachment of the leadframe/ringframe subassembly. This restriction on the assembly process limits the number of available variations in the assembly process.

### SUMMARY OF THE INVENTION

Briefly, and in general terms, the invention is directed to packages for high power and high operating-temperature integrated circuit devices having coefficient-of-thermal expansion (CTE) mismatches between package components. In one aspect, a circuit package having a temperature range of operation, includes a heat sink (also referred to herein as a flange), a die positioned on the heat sink and a thermally conductive adhesive layer between the heat sink and die. The adhesive has a modulus of elasticity that allows for deformation of the layer due to relative movement between the heat sink and die, over the temperature range of operation.

In another aspect, the invention is directed to lead-free packages that include a heat sink and a die secured to the heat sink through a lead-free first attachment element. The attachment element may be a layer of flexible, thermally conductive or a lead-free solder material.

In yet another aspect, the invention relates to a method of assembling a circuit package. The method includes securing a die to a heat sink using a layer of flexible, thermally conductive adhesive; securing a ringframe to the heat sink using a layer of flexible adhesive; and securing a leadframe to the ringframe using a layer of flexible adhesive.

These and other aspects and advantages of the invention will become apparent from the following detailed description and the accompanying drawings which illustrate by way of example the features of the invention.

### BRIEF DESCRIPTION OF THE DRAWINGS

FIG. 1 is a perspective view of a prior art circuit package

FIG. 2 is a perspective view of a circuit package;

FIG. 3 is a perspective view of the circuit package of FIG. 2 with the lid removed;

FIG. 4 is a sectional view of the circuit package of FIG. 2 taken along line 4-4 of FIG. 3; and

FIG. 5 is a flowchart of a process of assembling a circuit package.

### DETAILED DESCRIPTION OF THE PREFERRED EMBODIMENTS

The present invention allows for the fabrication of circuit packages using materials that are not necessarily CTE compatible. Flexible, adhesive materials are used to secure the package components together. More specifically, the die is secured to the heat sink, the ringframe to the heat sink and the leadframe to the ringframe, using epoxy materials that flex over the operational temperature range of the circuit package. The flexibility of the adhesives accommodates large differences in expansion and contraction of CTE-mismatched materials. Thus, the heat sink and ringframe materials are neither restricted to CTE-compatible materials nor to materials that are compatible with high-temperature attachment processes, such as typical brazing techniques. Because of this, a greater variety of materials may be used, including some lower cost, higher thermally conductive materials. Likewise, a greater variety of materials may be used for the leadframe. Adhesive mounting of the die avoids the use of lead based solders used in typical assembly processes. Thus, lead free packages may be fabricated. Lead free Ag/Sn or Au/Sn preforms may also be used to assembly a lead free circuit package.

It will be understood that when an element is referred to as being “on” another element, it can be directly on the other element or intervening elements may also be present. It will also be understood that if part of and element, such as a surface, is referred to as “inner”, it is farther from the outside of the device than other parts of the element. Furthermore, relative terms such as “beneath”, “below”, “top” or “bottom” may be used herein to describe a relationship of one element, layer or region to another element, layer or region. It will be understood that these terms are intended to encompass different orientations of the device in addition to the orientation depicted in the figures. Finally, the term “directly” means that there are no intervening elements.

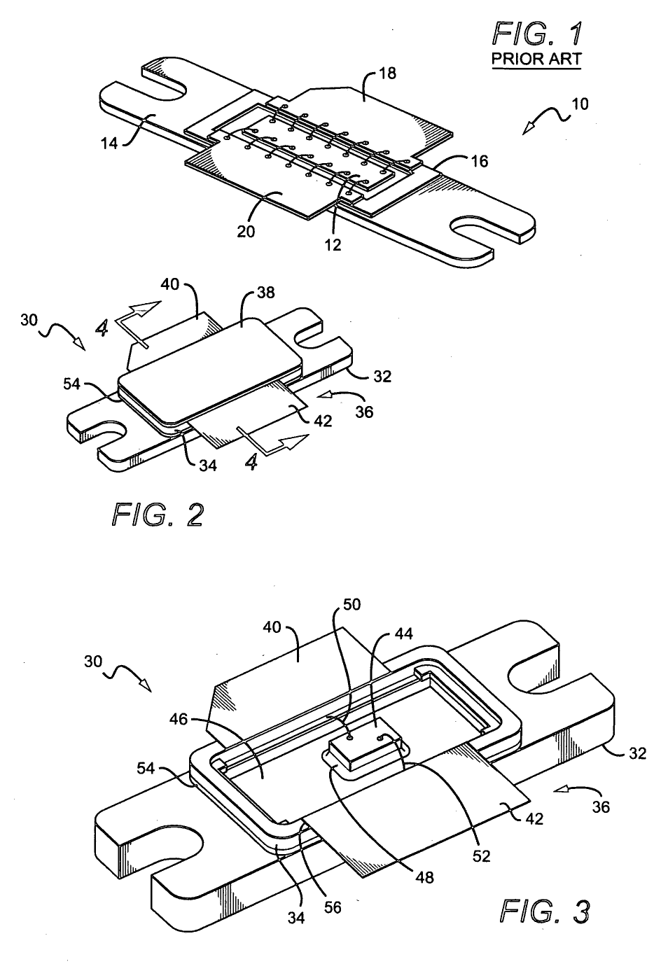

Referring now to the drawings and particularly to FIGS. 2 and 3, there is shown a circuit package 30 that includes a flange (heat sink) 32, a ringframe 34, a leadframe 36 and a lid 38. The leadframe 36 includes two leads 40, 42. The ringframe 34 electrically insulates the leads 40, 42 from the flange 32 and the leads from each other. A die 44 is attached to a die-attach area 46 on the flange 32. The die 44 (having a transistor) typically includes various layers of semiconductor materials on a substrate. The die 44 is electrically connected to the leads 40, 42 by wires 50 and 52, which are preferably ultrasonically bonded to the leads 40, 42. For clarity, only one die 44 is shown in the package 30 (FIG. 3), although it is understood that two or more die can be attached to the die-attach area 46.

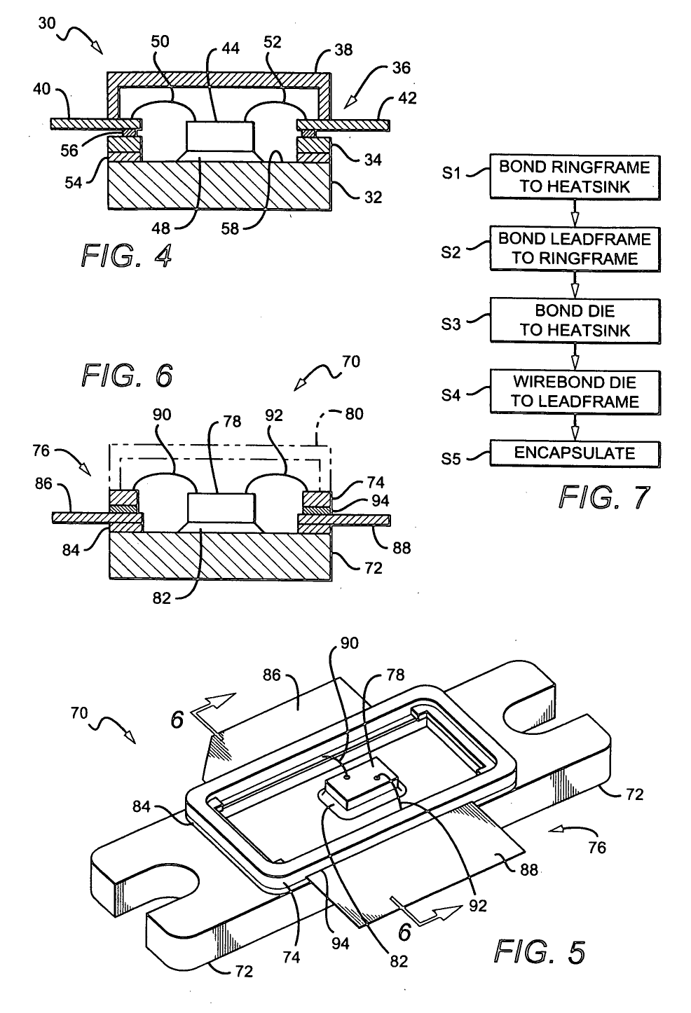

With reference to FIGS. 2 and 3 in conjunction with FIG. 4, the die 44 is secured to the flange 32 through a first attachment element 48, which as explained further below, may be a layer of adhesive material or a solder material. The ringframe 34 is secured to the flange 32 through a second attachment element 54 and the leadframe 36 is secured to the ringframe 34 through a third attachment element 56. As also explained further below, these second and third attachment elements 54, 56 are preferably layers of adhesive material.

As explained further below, each of the flange 32, ringframe 34, leadframe 36 and die 44 has an associated coefficient of thermal expansion (CTE). The CTEs of the flange 32, ringframe 34, leadframe 36 are determined by the material from which they are formed; while the CTE of the die 44 is largely determined by its substrate material.

The die 44 can be many different semiconductor devices arranged in many different ways. In some embodiments according to the present invention, the die 44 can comprise LDMOS having one or more transistors formed on it, while in others the die 44 can comprise one or more transistors in other arrangements, such as being mounted directly within the package 30. In one embodiment, the die comprises one or more Group III nitride based devices such as an AlGaN base high electron mobility transistors (HEMT) or field effect transistors (FET) alone or in combination with other devices and layers. The Group III nitride based device can be grown on a sapphire, SiC, GaN, AlN or Si wafer (or substrate). Group III nitrides refer to those semiconductor compounds formed between nitrogen and the elements in the Group III of the periodic table, usually aluminum (Al), gallium (Ga), and indium (In). The term also refers to ternary and tertiary compounds such as AlGaN and AlInGaN.

The wafer material may form the substrate of the die 44 and is the portion of the die that is attached to the die-attach area 46 (FIG. 3). The preferred wafer material is a 4H polytype of SiC, which has a coefficient of thermal expansion (CTE) of between 3 and 4 parts-per-million (ppm)/C.°. Other SiC polytypes can also be used including 3C, 6H and 15R polytypes. An AlxGa1-xN buffer layer (where x in between 0 and 1) can be included between the wafer and device active layers to provide an appropriate crystal structure transition between the SiC wafer (substrate) and the active layers.

Generally, SiC wafers are preferred over sapphire and Si because they have a much closer crystal lattice match to Group III nitrides, which results in Group III nitride films of higher quality. SiC also has a very high thermal conductivity so that the total output power of Group III nitride devices on SiC is not limited by the thermal resistance of the wafer (as is the case with some devices formed on sapphire or Si). Also, the availability of semi insulating SiC wafers provides the capacity for device isolation and reduced parasitic capacitance that make commercial devices possible. SiC substrates are available from Cree Inc., of Durham, N.C. and methods for producing them are set forth in the scientific literature as well as in a U.S. Pat. Nos. Re. 34,861; 4,946,547; and 5,200,022. Other possible substrate materials include silicon (Si), gallium nitride (GaN) and aluminum nitride (AlN). Gallium arsenide (GaAs) is another possible substrate material.

With continuing reference to FIGS. 2-4, the die 44 is attached to the flange 32 using a thermally conductive element 48 located between the die 44 and the heat sink 32 and preferably in direct contact with the facing surfaces of these components. The facing surfaces of the flange 32 and die 44 define an attachment surface area for the flange/die interface.

In one embodiment, the thermally conductive element 48 is a flexible, thermal adhesive, such as those available from Diemat (www.diemat.com), although other materials can also be used. The flexible, thermal adhesive 48 between the die 44 and the flange 32 has a low modulus of elasticity, or Young's modulus, (between 85 kpsi and 800 kpsi) and flexes over the temperature range of operation of the package, which may be between −50° C. and +150° C. Because of its flexibility, the layer of adhesive 28 deforms, e.g., expands and contracts, in response to relative movement between the flange 32 and the die 44. The flexible, thermal adhesive 48 bonds the die 44 to the flange 32 and conducts heat away from the die 44 and into the flange 32. The flexible, thermal adhesive 48 preferably has a thermal conductivity of between 5 W/m ° K and 60 W/m ° K, although materials with other thermal conductivities can also be used.

Because the thermal adhesive 48 is also flexible over the range of operation of the package, the flange 32 and the die 44 may be CTE mismatched. “CTE mismatched” means materials that are not thermally compatible (due to thermal expansion and contraction) over a temperature operating range. For example, for a circuit package having a temperature operating range between −50° and +150° C., the die 44 substrate may be formed of SiC having a CTE of between approximately 3 and 4 ppm/C. ° while the flange 32 may be formed of a material having a CTE of approximately 10 ppm/C. ° or greater. In a preferred embodiment, the flange 32 is formed of pure copper, which has a CTE of approximately 17 ppm/C. ° and is also highly thermally conductive, although the flange can be made of other materials.

In another embodiment, the thermally conductive element 48 is a Au/Si or Au/Sn preform, which has a thermal conductivity of between 40 W/m ° K and 60 W/m ° K. The preform is inserted between the die 44 and the flange 32 and is heated to its melting point to secure the die to the flange. The preforms, however, are not flexible over the operating range of the circuit package; thus the die 44 and flange 32 are necessarily CTE compatible. In this case, the die 44 substrate may be formed of, for example, SiC having a CTE of between 3 and 4 ppm/C. ° while the flange 32 may be formed of a material having a CTE of less than 10 ppm/C. ° . Possible CTE compatible materials for the flange 32 include CuMoCu and WCu, which have CTEs of around 6-10 ppm/C. °.

Because die-to-heat sink attachment by either of a above-described flexible, thermal adhesive material or a preform element avoids the use of tin/lead solder, the circuit package may be lead free. This allows for compliance with some new industry standards, such as current European standards, which mandate lead free circuit packages.

With reference to FIG. 4, the ringframe 34 is secured to the flange 32 using a second attachment element 54 that is preferably a first boundary layer of flexible, adhesive material deposited between the flange and the ringframe and preferably in direct contact with the facing surfaces of each component. The facing surfaces of the flange 32 and ringframe 34 define an attachment surface area for the heat sink/ringframe interface. The first boundary layer 54 between the flange 32 and the ringframe 34 preferably has a low modulus of elasticity, or Young's modulus (between 85 kpsi and 800 kpsi) and flexes over the temperature range of operation of the package, which may be between −50° C. and +150° C. Because of its flexibility, the first boundary layer 54 deforms in response to relative movement between the flange 32 and the ringframe 34.

Given the relative sizes of the ringframe 34 and the die 44, the flange/ringframe attachment surface area is relatively large, particularly when compared to the die/flange attachment surface area. In terms of thermally induced expansion or contraction, the larger the attachment area of two components, the greater the degree of relative movement between the two components will be and thus the greater the likelihood of mechanical failure of one or both components. Because of this, it is preferred that the first boundary layer 54 between the ringframe 34 and the flange 32 have a higher degree of flexibility than the adhesive material 48 between the flange and the die 44. For example, in a preferred embodiment, first boundary layer 54 between the ringframe 34 and the flange 32 has a modulus of elasticity of 500 kpsi and the adhesive material 48 between the flange 32 and the die 44 has a modulus of elasticity of approximately 700 kpsi.

Because the first boundary layer 54 is also flexible over the range of operation of the package, the flange 32 and the ringframe 34 may be CTE mismatched. For example, for a circuit package having a temperature operating range between −50° and +150° C., the ringframe 34 may be formed of ceramic having a CTE of between approximately 7 and 9 ppm/C. ° while the flange 32 may be formed of a material having a CTE of approximately 13 ppm/C. ° or greater. In a one embodiment, the flange 32 is formed of pure copper, which has a CTE of approximately 17 ppm/C. °. In another embodiment, the flange 32 is formed of Alumina, which has a CTE of approximately 27 ppm/C. °.

Because little heat is conducted through the ringframe/flange interface, it is not necessary for the first boundary layer 54 to be as thermally conductive as the adhesive material 48 between the flange 32 and the die 44. For example, the first boundary layer 54 may have a thermal conductivity less than 4 W/m ° K, although materials with different thermal conductivity can also be used.

The use of a first boundary layer 54 to secure the ringframe 34 to the flange 32 eliminates the use of brazing materials and thus the introduction of Sn or Ag into the circuit package. Thus the previously noted potential package reliability issues due to migration of Sn and Ag are avoided.

With continued reference to FIG. 4, the leadframe 36 is secured to the ringframe 34 using a second attachment element 56 that is preferably a second boundary layer of flexible, adhesive material deposited between the leadframe and the ringframe and preferably in direct contact with the facing surfaces of each component. The facing surfaces of the leadframe 36 and ringframe 34 define an attachment surface area for the leadframe/ringframe interface. The second boundary layer 56 between the leadframe 36 and the ringframe 34 has a low modulus of elasticity, or Young's modulus (between 85 kpsi and 800 kpsi) and flexes over the temperature range of operation of the package, which may be between −50° C. and +150° C. Because of its flexibility, the second boundary layer 56 deforms in response to relative movement between the leadframe 36 and the ringframe 34.

Because the second boundary layer 56 is also flexible over the range of operation of the package, the leadframe 36 and the ringframe 34 may be CTE mismatched. For example, for a circuit package having a temperature operating range between −50° and +150° C., the ringframe 34 may be formed of ceramic having a CTE of between approximately 7 and 9 ppm/C. ° while the leadframe 36 may be formed of a material having a CTE of approximately 13 ppm/C. ° or greater. In a preferred embodiment, the leadframe 36 is formed of pure copper, which has a CTE of approximately 17 ppm/C. °.

Regarding thermal conductivity, because little heat is conducted through the ringframe/leadframe interface, it is not necessary for the second boundary layer 56 to be as thermally conductive as the adhesive material 48 between the die 44 and the flange 32. For example, the flexible, adhesive material 56 may have a thermal conductivity less than 4 W/m ° K.

Given the relative sizes of the flange/ringframe attachment surface area and the leadframe/ringframe attachment the second boundary layer 56 may have a lower degree of flexibility relative to the flexible, adhesive material 54 between the flange 32 and ringframe 34. However, in a preferred embodiment, both the second boundary layer 56 and the first boundary layer 54 have a modulus of elasticity of 500 kpsi.

Because each of the adhesive 48 and boundary layers 54, 56 securing the die 44 to the flange 32, the ringframe 34 to the flange, and the leadframe 36 to the ringframe, flexes over the temperature range of operation of the package, any expansion and contraction differences between the materials of die 44 and the flange 32, the ringframe 34 and the flange 32, and the ringframe 34 and the leadframe 36 are accommodated by the temperature-induced flexing of the adhesives. The adhesive 48 and layers 54, 56 create a flexible condition (as opposed to rigid) between the components that allow the components to move relative to each other at different rates over a temperature range. Thus, in accordance with the present invention, it is not necessary for the flange 32 and die 44, the flange and ringframe 34, and the leadframe 36, to be CTE compatible.

In one configuration, each of the flange 32 and the leadframe 36 is made of pure copper which has a CTE of 17 ppm/C. °, the die 44 includes a SiC substrate which has a CTE of 3 and 4 ppm/C. °, and the ringframe 34 is formed of ceramic which has a CTE of between 7 and 9 ppm/C. °. In addition to pure copper, the flange 32 may be formed of copper alloys (e.g., CuMoCu, WCu), AlSiC or equivalents, which have CTE range between 6 and 10 ppm/C. °. Other possible ringframe 34 materials include Alumina, G TEK, LCP material, PCB or equivalents, which have CTEs ranging between 6 and 27 ppm/C. °. Other possible leadframe 36 materials include Kovar, BeCu or equivalents, which have CTEs ranging between 4 and 27 ppm/C. °.

With respect to the flange 32, pure copper is preferred because it has a high thermal conductivity and is a superior flange compared to copper alloys. It is also less expensive than copper alloys. Because of its high thermal conductivity, the flange 32 does not require additional features such as moats, which may be necessary in other flanges to increase thermal efficiencies. As illustrated in FIG. 4, in a preferred embodiment the mounting surface 58 of the flange 12 is substantially planar cross section.

With reference to FIGS. 3 and 4, in one exemplary package configuration, the flange 32 is approximately 230 mil×800 mil and is 62 mil thick, where one mil is 0.001 inch. The flange 32 is formed of pure copper having a CTE of approximately 27 ppm/C. ° and is coated with a 100 microinch (mi) layer of nickel and a 5 mi layer of gold. The ringframe 34 has internal dimensions of approximately 110 mil×260 mil, external dimensions of approximately 230 mil×360 mil, a height of approximately 20 mils, and is formed of a ceramic material having a CTE of between 7 and 9 ppm/C. °. The leadframe 36 is formed of pure copper and is coated with a 5 mil layer of gold. The lid 38 is plastic or ceramic and has a height of 70 mil.

The ringframe 34 is secured to the flange 32 by a 2 mil boundary layer of Diemat 6630 adhesive, which has a modulus of elasticity of approximately 500 kpsi and a thermal conductivity of approximately 45 W/m ° K. The die 44 is secured to the flange 32 by a 2 mil boundary layer of Emerson-Cuming 12875-1 adhesive, which has a modulus of elasticity of approximately 700 kpsi and a thermal conductivity of less than 4 W/m ° K. The leadframe 36 is also secured to the ringframe 34 by a 2 mil boundary layer of Emerson-Cuming 12875-1 adhesive.

It is understood that the above dimensions and material described above are only one example of an embodiment of a package according to the present invention. Other packages according to the invention can have other dimensions and can be made of other materials.

Circuit packages according to the present invention can also have features arranged in many different ways beyond the arrangement shown in package 30 in FIGS. 2-4 with the. FIGS. 5 and 6 show another embodiment of a package 70 according to the present invention also comprising a flange (heat sink), ringframe 74, leadframe 76, die 78, and lid 80 (shown in phantom in FIG. 6). These elements are similar to the corresponding elements shown in FIGS. 2-3 and can have similar dimensions. Similar to the package 30 in FIGS. 2-4, the die 78 in package 70 is mounted to the flange 72 by a thermally conductive element 82 which can be made of the same materials described above for thermally conductive element 48, such as Diemat, Au/Si or Au/Sn. It is understood, however, that many other materials can also be used for element 82.

The leadframe 76 comprises first and second leads 86, 88 that are electrically connected to the die 78 by wires 90, 92. In contrast to the package 30, the leadframe 76 in package 70 is arranged below the ringframe 74, between the ringframe 74 and the flange 72. The ringframe 74 is secured to the flange 72 by a first boundary layer of flexible and adhesive material 84 deposited between the flange 72 and the ringframe 74, similar to first boundary layer 54 shown in FIGS. 2-4 and described above and can be made of the same materials. At the first and second leads 86, 88 the first boundary layer 84 runs between the leads 86, 88 and the top surface of the flange 72. A second boundary layer 94 is provided between the ringframe 74 and the first and second leads 86, 88, that is similar to the boundary layer 56 shown in FIGS. 2-4 and described above, and is made of the same flexible, adhesive material. By including the boundary layers 84, 94, and the thermally conductive element 82, that package 70 can be used with high power and high operating-temperature integrated circuit devices and with package elements having CTE mismatches as described above.

With reference to FIG. 7, in an exemplary process, a circuit package configured in accordance with the invention is assembled by first securing or bonding a ringframe to a heat sink using a flexible adhesive material (step S1). At step S2, a leadframe is secured to the ringframe/heat sink subassembly, also using a flexible adhesive material. Next, a die is attached to the heat sink (step S3), using a flexible, thermally conductive adhesive material. At steps S4 and S5 respectively, the die is wirebonded to the leadframe and encapsulated.

Due to the use of adhesive materials in each bonding step, it is not necessary that the components be attached in a particular order, as would be required if any high-temperature attachment techniques were used. For example, if the die were attached to the heat sink using high-temperature brazing, it would necessarily follow that the die would have to be attached prior to any adhesive bonding steps. Otherwise, the adhesive bonded components would separate during the subsequent high-temperature processes. In a preferred embodiment, each of the adhesive materials is also capable of withstanding reflow peak temperature of 265° C. for 90 seconds, which is a typical reflow profile for packages that are soldered into a higher level assemblies using no lead solders.

Returning to FIG. 5, while the components are described as being assembled in a particular order, due to the absence of any high-temperature attachment processes, it is possible to depart from the order shown. For example, a leadframe/ringframe subassembly may be formed by bonding these two components together, separate from the heat sink and then bonding the subassembly to the heat sink. It is also possible to attach the die to the heat sink at any point during the assembly process. For example, the die may be attached to the heat sink prior to attachment of the ringframe or immediately after attachment of the ringframe, but prior to attachment of the leadframe to the ringframe.

It will be apparent from the foregoing that while particular forms of the invention have been illustrated and described, various modifications can be made without departing from the spirit and scope of the invention. Accordingly, it is not intended that the invention be limited, except as by the appended claims.

We claim:

1. A circuit package having a temperature range of operation, said circuit comprising:
a heat sink;
a die positioned on the heat sink; and
a thermally conductive adhesive layer between the heat sink and die, the adhesive having a modulus of elasticity that allows for deformation of the layer due to relative movement between the heat sink and die, over the temperature range of operation.

2. The package of claim 1 wherein the coefficient of thermal expansion of the heat sink is mismatched with respect to the die, over the temperature range of operation.

3. The package of claim 1 wherein the temperature range of operation is between approximately −50° C. and +150° C., the heat sink has a coefficient of thermal expansion of at least approximately 10 ppm/C. °, and the die has a coefficient of thermal expansion of at most approximately 4 ppm/C. °.

4. The package of claim 1 wherein the modulus of elasticity of the adhesive between the heat sink and the die is between 85 kpsi and 800 kpsi.

5. The package of claim 1 wherein the thermal conductivity of the adhesive between the heat sink and the die is between 5 W/m ° K and 60 W/m ° K.

6. The package of claim 1 further comprising:
a ringframe positioned around the die; and
an adhesive layer between the heat sink and ringframe, the adhesive having a modulus of elasticity that allows for deformation of the layer due to relative movement between the heat sink and ringframe, over the temperature range of operation.

7. The package of claim 6 wherein the coefficient of thermal expansion of the ringframe is mismatched with respect to the heat sink, over the temperature range of operation.

8. The package of claim 6 wherein the temperature range of operation is between approximately −50° C. and +150° C., the heat sink has a coefficient of thermal expansion of at least approximately 13 ppm/C. °, and the ringframe has a coefficient of thermal expansion of at most approximately 9 ppm/C. °.

9. The package of claim 6 wherein the modulus of elasticity of the adhesive between the heat sink and the ringframe is between 85 kpsi and 800 kpsi.

10. The package of claim 6 wherein the thermal conductivity of the adhesive between the heat sink and the ringframe is less than the thermal conductivity of the adhesive between the die and the heat sink.

11. The package of claim 1 further comprising:
a leadframe positioned on either side of the die; and
an adhesive layer between the leadframe and ringframe, the adhesive having a modulus of elasticity that allows for deformation of the layer due to relative movement between the leadframe and ringframe, over the temperature range of operation.

12. The package of claim 11 wherein the coefficient of thermal expansion of the leadframe is mismatched with respect to the ringframe, over the temperature range of operation.

13. The package of claim 11 wherein the temperature range of operation is between approximately −50° C. and +150° C., the leadframe has a coefficient of thermal expansion of at least approximately 13 ppm/C. °, and the ringframe has a coefficient of thermal expansion of at most approximately 9 ppm/C. °.

14. The package of claim 11 wherein the modulus of elasticity of the adhesive between the leadframe and the ringframe is between 85 kpsi and 800 kpsi.

15. The package of claim 11 wherein the thermal conductivity of the adhesive between the leadframe and the ringframe is less than the thermal conductivity of the adhesive between the die and the heat sink.

16. A circuit package comprising:
a heat sink; and
a die secured to the heat sink through a lead-free first attachment element.

17. The package of claim 16 wherein the first attachment element is a layer of flexible, thermally conductive adhesive material located between the die and the heat sink.

18. The package of claim 17 wherein the adhesive has a modulus of elasticity that allows for deformation of the layer due to relative movement between the heat sink and die, over a temperature range of operation.

19. The package of claim 18 wherein the die and the heat sink are CTE mismatched.

20. The package of claim 16 wherein the first attachment element comprises a lead-free solder material located between the die and the heat sink.

21. The package of claim 20 wherein the die and heat sink are CTE compatible over a temperature range of operation

22. The package of claim 16 further comprising a ringframe positioned around the die and secured to the heat sink through a lead-free second attachment element.

23. The package of claim 22 wherein the second attachment element is a layer of flexible adhesive material located between the ringframe and the heat sink.

24. The package of claim 23 wherein the adhesive has a modulus of elasticity that allows for deformation of the layer due to relative movement between the heat sink and ringframe, over a temperature range of operation.

25. The package of claim 24 wherein the ringframe and the heat sink are CTE mismatched.

26. The package of claim 16 further comprising a leadframe positioned on either side of the die and secured to the ringframe through a lead-free third attachment element.

27. The package of claim 26 wherein the third attachment element is a layer of flexible adhesive material located between the leadframe and the ringframe.

28. The package of claim 27 wherein the adhesive has a modulus of elasticity that allows for deformation of the layer due to relative movement between the leadframe and ringframe, over a temperature range of operation.

29. The package of claim 28 wherein the ringframe and the leadframe are CTE mismatched.

30. A method of assembling a circuit package comprising:
securing a die to a heat sink using a layer of flexible, thermally conductive adhesive;
securing a ringframe to the heat sink using a layer of flexible adhesive; and
securing a leadframe to the ringframe using a layer of flexible adhesive.

31. The method of claim 30 wherein the die may be secured to the heat sink before or after the ringframe is secured to the heat sink.

32. The method of claim 30 wherein the die may be secured to the heat sink before or after the leadframe is secured to the ringframe.

33. The method of claim 30 wherein the leadframe may be secured to the ringframe before or after the ringframe is secured to the heat sink.

34. The method of claim 30 wherein the adhesive securing the die to the heat sink has a modulus of elasticity that allows for deformation of the layer due to relative movement between the heat sink and die, over the temperature range of operation of the circuit package.

35. The method of claim 30 wherein the adhesive securing the ringframe to the heat sink has a modulus of elasticity that allows for deformation of the layer due to relative movement between the heat sink and ringframe, over the temperature range of operation of the circuit package.

36. The method of claim 30 wherein the adhesive securing the leadframe to the ringframe has a modulus of elasticity that allows for deformation of the layer due to relative movement between the leadframe and ringframe, over the temperature range of operation of the circuit package.

37. The method of claim 30 wherein each of the layers of adhesive is able to withstand a temperature of approximately 265° C. for up to about 90 seconds.
